(19) United States
(12) Patent Application Publication
(10) Pub. No.: US 2023/0411484 A1
(43) Pub. Date: Dec. 21, 2023

(54) SEMICONDUCTOR ELECTRONIC DEVICES INCLUDING SIDEWALL BARRIER LAYERS AND METHODS OF FABRICATING THE SAME

(71) Applicant: CORNING INCORPORATED, CORNING, NY (US)

(72) Inventors: Hoon Kim, Horseheads, NY (US); Robert George Manley, Ocala, FL (US)

(21) Appl. No.: 18/035,159

(22) PCT Filed: Nov. 10, 2021
(86) PCT No.: PCT/US2021/058701

§ 371 Date: May 3, 2023

Related U.S. Application Data
(60) Provisional application No. 63/114,569, filed on Nov. 17, 2020.

(51) Int. Cl. H01L 29/45; H01L 29/786; H01L 29/417; H01L 29/40; H01L 21/02; C23C 16/50; C23C 16/40; C23C 16/448

(52) U.S. Cl. CPC H01L 29/458; H01L 29/786; H01L 29/41733; H01L 29/401; C23C 16/4482; H01L 21/02205; H01L 21/02274; C23C 16/50; C23C 16/40; H01L 21/02175

(57) ABSTRACT

The present disclosure includes a semiconductor device comprising a substrate including a device surface and a patterned metallic electrode disposed on the substrate. The patterned metallic electrode is formed of one or more of copper, gold, and silver. The patterned metallic electrode comprises a lower surface proximate to the substrate, an upper surface, and a sidewall extending between the lower surface and the upper surface a sidewall barrier layer extending over the sidewall. The sidewall barrier layer may be a manganese oxide barrier layer.

### CROSS-REFERENCE TO RELATED APPLICATIONS

This application claims the benefit of priority under 35 U.S.C. § 119 of U.S. Provisional Ser. No. 63/114,569 filed on Nov. 17, 2020, the content of which is relied upon and incorporated herein by reference in its entirety.

### FIELD

The present specification generally relates to semiconductor electronics and, more particularly, to semiconductor electronic devices comprising metallic electrodes having sidewall barrier layers disposed thereon, and methods of their manufacture.

### TECHNICAL BACKGROUND

Copper electrodes offer several advantages over other types of electrodes due to their relatively low electrical resistivity. The presence of metals such as copper in a semiconductor device, however, can result in various complications in the fabrication process. For example, copper may diffuse into neighboring semiconductor layers, increasing the leakage current therethrough. Moreover, if copper is exposed to oxygen, it may become oxidized and adversely impact the conductivity of the electrode. Such oxidation concerns are especially acute if the copper is exposed to oxygen at elevated temperatures, such as during the formation of additional semiconductor device components (e.g., passivation layers).

### SUMMARY

A first aspect of the present disclosure includes a semiconductor device comprising: a substrate including a device surface and a patterned metallic electrode disposed on the substrate. The patterned metallic electrode is formed of one or more of copper, gold, and silver. The patterned metallic electrode comprises a lower surface proximate to the substrate, an upper surface, and a sidewall extending between the lower surface and the upper surface a sidewall barrier layer extending over the sidewall.

A second aspect of the present disclosure includes a semiconductor device according to any of the first aspect, wherein the sidewall barrier layer comprises a magnesium oxide barrier layer.

A third aspect of the present disclosure includes a semiconductor device according to any of the first through the second aspects, wherein the sidewall barrier layer comprises a thickness of greater than or equal to 1 nm and less than or equal to 5 nm.

A fourth aspect of the present disclosure includes a semiconductor device according to any of the first through the third aspects, further comprising: a first barrier layer contacting the lower surface and disposed between the patterned metallic electrode and the substrate; and a second barrier layer contacting the upper surface, wherein neither the first barrier layer nor the second barrier layer directly contacts the sidewall.

A fifth aspect of the present disclosure includes a semiconductor device according to any of the first through the fourth aspects, wherein the sidewall barrier layer is disposed between the first barrier layer and the second barrier layer directly on the sidewall.

A sixth aspect of the present disclosure includes a semiconductor device according to any of the first through the fifth aspects, further comprising an oxide-containing passivation layer disposed on the patterned metallic electrode, the oxide-containing passivation layer directly contacting at least a portion of a the sidewall barrier layer.

A seventh aspect of the present disclosure includes a semiconductor device according to any of the first through the sixth aspects, further comprising: a gate electrode disposed on the substrate; a dielectric layer disposed on the gate electrode; a semiconductor layer disposed on the dielectric layer; a source electrode disposed on a first portion of the semiconductor layer; and a drain electrode disposed on a second portion of the semiconductor layer. The source electrode and the drain electrode overlap the gate electrode in a direction extending perpendicular to the device surface at first and second gate overlap regions. The patterned metallic electrode is one of the source electrode and the drain electrode such that the sidewall barrier layer directly contacts the source electrode or the drain electrode.

An eighth aspect of the present disclosure includes a semiconductor device according to any of the first through the seventh aspects, wherein the other of the source electrode and the drain electrode that is not the patterned metallic electrode comprises a lower surface proximate to the substrate, an upper surface, and an additional sidewall extending between the lower surface and the upper surface, the semiconductor device further comprising an additional sidewall barrier layer disposed locally over the additional sidewall.

A ninth aspect of the present disclosure includes a semiconductor device according to any of the first through the eighth aspects, wherein lengths of the first and second gate overlap regions differ from one another by less than or equal to 10 nm.

A tenth aspect of the present disclosure includes a semiconductor device according to any of the first through the ninth aspects, further comprising a passivation layer disposed on the source electrode and the drain electrode, the passivation layer containing an oxide, wherein the passivation layer directly contacts at least a portion of the sidewall and the additional sidewall.

An eleventh aspect of the present disclosure includes a semiconductor device according to any of the first through the eleventh aspects, further comprising an additional metallic layer disposed on the source electrode and the drain electrode.

A twelfth aspect of the present disclosure includes a semiconductor device according to any of the first through the second eleventh aspects, further comprising a copper barrier layer disposed locally over the gate electrode, the copper barrier layer directly contacting the gate electrode.

A thirteenth aspect of the present disclosure includes a semiconductor device according to any of the first through the twelfth aspects, wherein the patterned metallic electrode is a component of a thin film transistor.

A fourteenth aspect of the present disclosure includes a semiconductor device according to any of the first through the thirteenth aspects, wherein the thin film transistor is a component of a touch panel display.

A fifteenth aspect of the present disclosure includes a method of fabricating a semiconductor electronic device, the method comprising: providing a substrate and forming a patterned electrode structure on the substrate. The patterned electrode structure comprises a first barrier layer disposed on the substrate; a metallic electrode layer disposed on the first barrier layer, the metallic electrode layer being formed of one or more of copper, gold, and silver; and a second barrier layer disposed on the upper surface of the metallic electrode layer. The first barrier layer, the metallic electrode layer, and the second barrier layer are patterned such that a sidewall of the metallic electrode layer is exposed between the first barrier layer and the second barrier layer. The method comprises: heating the substrate to a deposition temperature of at least 300° C.; and exposing the patterned electrode structure to a manganese precursor at the deposition temperature within a deposition chamber for a deposition period, wherein a pressure in the deposition temperature is at least 0.1 Torr during the deposition period. The deposition period is at least 1 second and the manganese precursor selectively migrates the sidewall. The method also comprises, after exposing the substrate to the manganese precursor, exposing the patterned electrode structure to an oxide that reacts with the manganese precursor to form an MnOₓ barrier layer disposed locally on the sidewall.

A sixteenth aspect of the present disclosure includes a method according to any of the fifteenth aspect, wherein the manganese precursor is a manganese amidinate having the structure

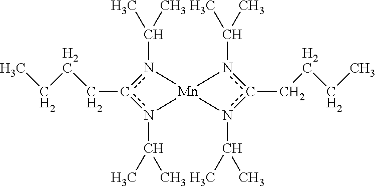

and is supplied to the deposition chamber via a bubbler in fluid communication with the deposition chamber.

A seventeenth aspect of the present disclosure includes a method according to any of the fifteenth through the sixteenth aspects, wherein the manganese precursor is a manganese amidinate having the structure

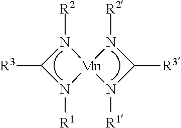

where R¹, R², R³, R^{1′}, R^{2′} and R^{3′} are groups made from one or more non-metal atoms.

A eighteenth aspect of the present disclosure includes a method according to any of the fifteenth through the seventh aspects, wherein R1, R2, R1′ and R2′ are isopropyl groups and R3 and R3′ are n-butyl groups.

An nineteenth aspect of the present disclosure includes a method according to any of the fifteenth through the eighteenth aspects, further comprising depositing an oxide-containing passivation layer on the patterned electrode structure, the oxide-containing passivation layer at least partially contacting the MnOₓ barrier layer.

A twentieth aspect of the present disclosure includes a method according to any of the fifteenth through the nineteenth aspects, wherein the oxide that reacts with the manganese precursor to form an MnOₓ barrier layer is a component of the oxide-containing passivation layer such that the MnOₓ barrier layer is formed during deposition of the oxide-containing passivation layer.

A twenty first aspect of the present disclosure includes a method according to any of the fifteenth through the twentieth aspects, wherein the oxide-containing passivation layer is deposited in a plasma enhanced chemical vapor deposition chamber.

A twenty second aspect of the present disclosure includes a method according to any of the fifteenth through the twenty first aspects, wherein the deposition chamber in which the patterned electrode layer structure is exposed to the manganese precursor corresponds to the plasma enhanced chemical vapor deposition chamber such that the patterned electrode structure remains in the plasma enhanced chemical vapor deposition chamber both for exposure to the manganese precursor and the deposition of the oxide-containing passivation layer.

A twenty third aspect of the present disclosure includes a method according to any of the fifteenth through the twenty second aspects, wherein the manganese precursor is introduced into the plasma enhanced chemical vapor deposition chamber via a bubbler in fluid communication with the plasma enhanced chemical vapor deposition chamber, wherein the bubbler is heated to a temperature that is greater than or equal to 75° C. and less than or equal to 100° C. prior to introducing the manganese precursor into the plasma enhanced chemical vapor deposition chamber.

A twenty fourth aspect of the present disclosure includes a method according to any of the fifteenth through the twenty first aspects, wherein the semiconductor electronic device is a thin film transistor device.

A twenty fifth aspect of the present disclosure includes a method of fabricating a thin film transistor, the method comprising: providing a substrate; depositing a gate electrode layer on a device surface of the substrate and patterning the gate electrode layer into a gate electrode; depositing a dielectric layer on the gate electrode layer; depositing a semiconductor on the dielectric layer; and forming a patterned electrode structure on the channel. The patterned electrode structure comprises a first barrier layer disposed on the semiconductor layer, an electrode layer disposed on the first barrier layer, and a second barrier layer disposed on the electrode layer. The electrode layer comprises a drain portion comprising a drain sidewall and a source portion comprising a source sidewall. The drain sidewall and the source sidewall are disposed over the gate electrode. The method also includes simultaneously forming sidewall barrier layers extending over the source and gate sidewalls and an oxide-containing passivation layer on the patterned electrode structure. Simultaneously forming the sidewall barrier layers and the oxide-containing passivation layer comprises placing the substrate and patterned electrode structure into a plasma enhanced chemical vapor deposition chamber in fluid communication with a bubbler containing a manganese precursor; flowing the manganese precursor into the deposition chamber for a predetermined period while the substrate and patterned electrode are heated to a deposition temperature; and flowing chemical components of the oxide-containing passivation layer into the deposition chamber such that an oxide reacts with the manganese precursor to form magnesium oxide sidewalls barrier layers on the source and gate sidewalls.

A twenty sixth aspect of the present disclosure includes a method according to the twenty fifth aspect, wherein the manganese precursor is a manganese amidinate having the structure

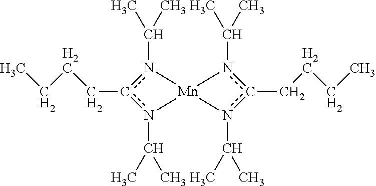

and is supplied to the deposition chamber via a bubbler in fluid communication with the deposition chamber.

A twenty seventh aspect of the present disclosure includes a method according to any of the twenty fifth through the twenty sixth aspects, wherein the manganese precursor is a manganese amidinate having the structure

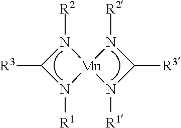

where R¹, R², R³, R^{1′}, R^{2′}, and R^{3′} are groups made from one or more non-metal atoms.

A twenty eighth aspect of the present disclosure includes a method according to any of the twenty fifth through the twenty seventh aspects, wherein R1, R2, R1′ and R2′ are isopropyl groups and R3 and R3′ are n-butyl groups.

A twenty ninth aspect of the present disclosure includes a method according to any of the twenty fifth through the twenty eighth aspects, wherein the electrode layer is formed of one or more of copper, gold, and silver.

A thirtieth aspect of the present disclosure includes a method according to any of the twenty fifth through the twenty ninth aspects, wherein the electrode layer is formed of pure copper.

A thirty first aspect of the present disclosure includes a method according to any of the twenty fifth through the thirtieth aspects, wherein the deposition temperature is greater than or equal to 300° C.

A thirty second aspect of the present disclosure includes a method according to any of the twenty fifth through the thirty first aspects, wherein the deposition temperature is greater than or equal to 350° C.

A thirty third aspect of the present disclosure includes a method according to any of the twenty fifth through the thirty second aspects, wherein the predetermined period is greater than or equal 15 minutes.

A thirty fourth aspect of the present disclosure includes a method according to any of the twenty fifth through the thirty third aspects, wherein the oxide-containing passivation layer comprises silica.

A thirty fifth aspect of the present disclosure includes a method according to any of the twenty fifth through the thirty fourth aspects, further comprising exposing the gate electrode to a manganese precursor at an elevated temperature prior to depositing the dielectric layer thereon.

### BRIEF DESCRIPTION OF THE DRAWINGS

The foregoing will be apparent from the following more particular description of the example embodiments, as illustrated in the accompanying drawings in which like reference characters refer to the same parts throughout the different views. The drawings are not necessarily to scale, emphasis instead placed upon illustrating the representative embodiments.

FIG. 1A schematically depicts a sectional view of a semiconductor electronic device, according to one or more embodiments described herein;

FIG. 1B schematically depicts a cross-sectional view of a patterned electrode structure of the semiconductor electronic device depicted in FIG. 1A, according to one or more embodiments described herein;

FIG. 1C schematically depicts a top-down view of an overlay of electrodes of the semiconductor electronic device depicted in FIG. 1A and associated gate overlap regions, according to one or more embodiments described herein;

FIG. 2 depicts a flow diagram of a method of forming a manganese oxide barrier layer on a sidewall of a metallic electrode, according to one or more embodiments described herein;

FIG. 3 schematically depicts a plasma enhanced chemical deposition reactor for fabricating semiconductor electronic devices comprising manganese oxide sidewall barrier layers, according to one or more embodiments described herein;

FIG. 4A schematically depicts a patterned electrode structure of a semiconductor electronic device after exposure to a manganese precursor, according to one or more embodiments described herein;

FIG. 4B schematically depicts the patterned electrode structure depicted in FIG. 4A after exposure to an oxide causes a formation of a manganese oxide sidewall barrier layer, according to one or more embodiments described herein; and

FIG. 5 is a flow diagram of a method of fabricating a thin film transistor device comprising at least one sidewall barrier layer, according to one or more embodiments described herein.

### DETAILED DESCRIPTION

Embodiments of the present specification pertain to semiconductor electronic devices comprising patterned electrode structures with sidewall barrier layers and methods for fabricating the same. The patterned electrode structures may comprise a patterned metallic electrode comprising a first surface disposed proximate to a substrate, a second surface, and a sidewall extending between the first surface and the second surface. In embodiments, the patterned electrode structures also comprise barrier layers disposed on the first and second surfaces to facilitate adhesion of the patterned metallic electrode to the substrate and/or prevent diffusion of the metal of the patterned metallic electrode into adjacent components of the semiconductor electronic device (e.g., a semiconductor or dielectric layer). The sidewall may be uncovered by the barrier layers disposed on the first and second surfaces as a result of the patterning of an electrode layer from which the patterned metallic electrode is formed. Accordingly, the semiconductor electronic devices disclosed herein may include a sidewall barrier layer that is formed directly on the sidewall after the patterning of the electrode layer. The sidewall barrier layers described herein may be formed by exposing the patterned electrode structures to a manganese precursor at a suitable deposition temperature. The manganese precursor may be present as a metallic phase within the patterned metallic electrode at the sidewall. After exposure to the manganese precursor, the patterned electrode structure may be exposed to an oxide that reacts with the manganese atoms present in the patterned metallic electrode to form a manganese oxide sidewall barrier layer. The sidewall barrier layer beneficially prevents oxidation of the patterned metallic electrode and improves operation of the semiconductor electronic device. Various embodiments of semiconductor electronic devices comprising patterned electrode structures with sidewall barrier layers and methods for fabricating the same will be described in further detail herein with specific reference to the appended drawings.

The sidewall barrier layers described herein may beneficially be formed during semiconductor device fabrication with minimal disruption to existing fabrication processes. For example, in embodiments, semiconductor electronic devices in accordance with the present specification may comprise an oxide-containing passivation layer disposed on the patterned electrode structure. The oxide-containing passivation layer may be disposed on the patterned electrode structure via plasma enhanced chemical vapor deposition (“PECVD”), where the substrate is heated and exposed to component gasses of the oxide-containing passivation layer. The manganese precursor used to form the sidewall barrier layers described herein may be introduced into the PECVD chamber prior to formation of the oxide-containing passivation layer, and react with oxygen contained in the component gasses, resulting in the simultaneous formation of the sidewall barrier layer and the oxide-containing passivation layer. As such, the sidewall barrier layers described herein may be efficiently formed with minimal modifications to existing device fabrication processes.

The sidewall barrier layers described herein beneficially improve semiconductor device performance by maintaining conductivity of the patterned metallic electrodes throughout the fabrication process. For example, one semiconductor electronic device that may be fabricated via the methods described herein is a thin film transistor (“TFT”) device comprising, among other components, a substrate, a gate electrode disposed on the substrate, a channel semiconductor layer, a source electrode, and a drain electrode. The source and drain electrodes may overlap the gate electrode in gate overlap regions defined at least in part by a source sidewall of the source electrode and a drain sidewall of the drain electrode. Sidewall barrier layers may be formed on the source and drain sidewalls to prevent oxidation thereof during the fabrication of the TFT device. Such oxidation prevention may serve to preserve variability in the size of the gate overlap regions of the source and drain electrodes. Inconsistencies in the size of the gate overlap regions caused by oxidation of the source and drain electrodes at the sidewalls may impact various operating characteristics (e.g., threshold voltage, scattering parameters, electron mobility, and leakage current) of the TFT device in unpredictable ways. As such, by reducing such oxidation and maintaining the variability of the gate overlap regions to within a predetermined threshold (e.g., less than or equal to 10 nm, less than or equal to 5 nm), the sidewall barrier layers described herein may maintain consistency in TFT device performance. Such consistency may improve the overall operating performance of devices incorporating TFT devices (e.g., touch panel displays, touch panels, and the like).

As used herein, the term “metallic electrode” refers to a pure metallic electrode layer of a semiconductor device formed from a sputtering target constructed of at least 99.99 at. % of a particular metal (e.g., Cu). In embodiments the metallic electrodes described herein are formed from a sputtering target having a purity of 6N or higher.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

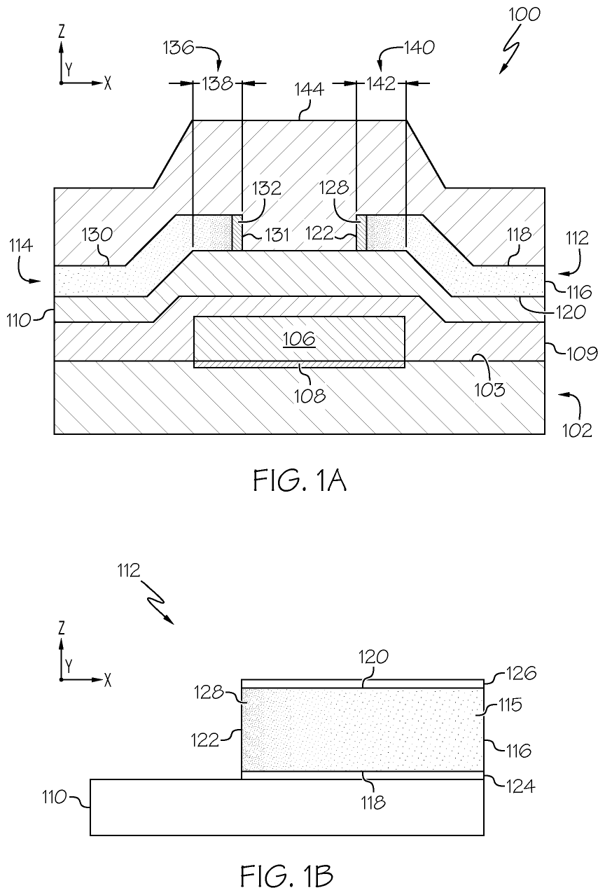

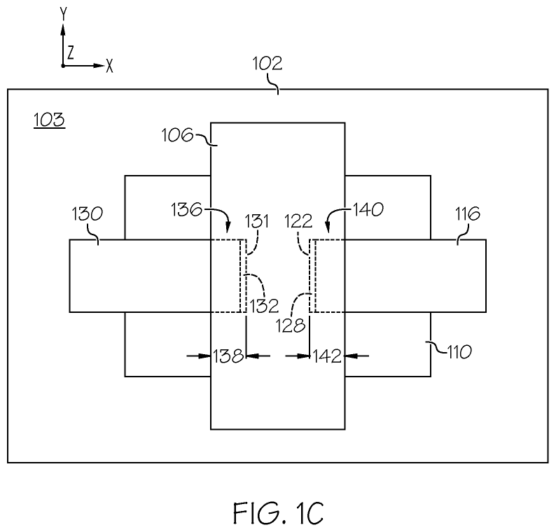

FIGS. 1A, 1, and 1C schematically depict a semiconductor electronic device 100 in accordance with the present disclosure. FIG. 1A schematically depicts a cross-sectional view of the semiconductor electronic device 100. FIG. 1B schematically depicts a cross-sectional view of first a patterned electrode structure 112 of the semiconductor electronic device 100. FIG. 1C schematically depicts a top-down view depicting the overlap of various components of the semiconductor electronic device 100. The semiconductor electronic device 100 depicted in FIGS. 1A, 1, and 1C is a bottom gate TFT device formed on a substrate 102. The semiconductor electronic device 100 comprises the substrate 102 and a gate electrode 106 disposed on a device surface 103 of the substrate 102. The gate electrode 106 may be a patterned electrode patterned (e.g., via any suitable etching technique) from a metallic layer (e.g., constructed of copper, gold, or silver) disposed on the device surface 103. An adhering layer 108 may be disposed between the gate electrode 106 and the substrate 102 to promote adhesion between the gate electrode 106 and the substrate 102. The adhering layer 108 may be patterned in conjunction with the gate electrode 106 such that the adhering layer 108 possesses a size and shape that largely corresponds to the gate electrode 106.

In embodiments, the substrate 102 may be constructed of glass, glass-ceramic, or ceramic material. Example glass materials include, but are not limited to, borosilicate glass (e.g., glass manufactured by Corning Incorporated of Corning, NY under the trade name Corning® Willow® Glass), alkaline earth boro-aluminosilicate glass (e.g., glass manufactured by Corning Incorporated under the trade name EAGLE XG®), alkaline earth boro-aluminosilicate glass (e.g., glass manufactured by Corning Incorporated under the trade name Contego Glass), and ion-exchanged alkali-aluminosilicate (e.g., glass manufactured by Corning Incorporated under the trade name Gorilla® Glass). It should be understood that other glass, glass ceramic, ceramic, multi-layers, or composite compositions may also be utilized for the substrate 102. Additionally, the substrate 102 may be constructed of materials other than glass, glass-ceramic, or ceramic material consistent with the present disclosure.

Referring to FIG. 1A, the semiconductor electronic device 100 further comprises a first dielectric layer 109 disposed on the substrate 100. The first dielectric layer 109 may cover the gate electrode 106 and directly contact the substrate 102. The first dielectric layer 109 may be formed of a plurality of different materials (e.g., silicon nitride, silicone oxide, silicon oxynitride, an elastomeric or other polymer-based dielectric layer, or any other suitable material) depending on the implementation. A semiconductor layer 110 is disposed on the first dielectric layer 109. The semiconductor layer 110 may be formed from an organic semiconductor material or an inorganic semiconductor material, depending on the implementation. In embodiments, the semiconductor layer 110 comprises a doped semiconductor layer comprising a channel region, a source region, and a gain region. Any suitable structure for the semiconductor layer 110 may be used consistent with the present disclosure. For example, in embodiments, the semiconductor layer 110 comprises an un-doped semiconductor layer (e.g., silicon) disposed on the first dielectric layer 109 and an n-doped semiconductor layer (e.g., constructed of n-doped amorphous silicon, n-doped microcrystalline silicon, n-doped polycrystalline silicon, amorphous oxides) disposed on the un-doped semiconductor layer. In embodiments, the un-doped semiconductor layer may be omitted. The semiconductor layer 110 may be patterned via any suitable technique

The semiconductor electronic device 100 further includes a first patterned electrode structure 112 and a second patterned electrode structure 114 disposed on the semiconductor layer 110. In embodiments, the first patterned electrode structure 112 comprises a drain electrode 116 extending over a drain region of the semiconductor layer 110 and the second patterned electrode structure 114 comprises a source electrode 130 extending over a source region of the semiconductor layer 110. In embodiments, the source electrode 130 and the drain electrode 116 are patterned from a metallic electrode layer that is disposed on the semiconductor layer 110 via any suitable deposition technique (e.g., sputtering) and subsequently etched. In embodiments, the metallic electrode layer from which the drain electrode 116 and the source electrode 130 are patterned is constructed from a pure metal, such as gold, silver, or copper. For example, in embodiments, the metallic electrode layer from which the source electrode 130 and drain electrode 116 are formed is constructed from pure copper via any suitable technique (e.g., magnetron sputtering) and comprises a thickness that is greater than or equal to 250 nm and less than or equal to 500 nm.

In embodiments where the source electrode 130 and the drain electrode 116 are constructed from a pure metallic layer, pure metals such as gold, copper, and silver may not adhere to the semiconductor layer 110. Moreover, the pure metal may diffuse into the semiconductor layer 110 and generate metallic silicides, resulting in a degradation of electrical performance of the semiconductor electronic device 100. Accordingly, as depicted in FIG. 1, the first patterned electrode structure 112 comprises a first barrier layer 124 disposed between the drain electrode 116 and the semiconductor layer 110. The first barrier layer 124 may improve the adhesion between the metallic electrode layer and the semiconductor layer 110 and prevent diffusion of the metal into the semiconductor layer 110. The first barrier layer 124 may be constructed from a variety of different materials depending on the implementation, including, but not limited to titanium, tantalum, and nitrides of tantalum or titanium. In embodiments, the first barrier layer 124 is blanket formed on the semiconductor layer 110.

The first patterned electrode structure 112 further includes a second barrier layer 126 disposed on the drain electrode 116. The second barrier layer 126 may prevent diffusion of the metal in the drain electrode 116 into a passivation or other dielectric layer disposed on the first patterned electrode structure 112 (e.g., the oxide-containing passivation layer 144 described herein). In embodiments, the second barrier layer 126 is blanket deposited on a metallic electrode layer 115 from which the drain electrode 116 is formed. In embodiments, the second barrier layer 126 may be formed of similar materials as the first barrier layer 124, although other materials (e.g., silicon carbide, silicon nitride) may also be used consistent with the present specification. In embodiments, the first barrier layer 124, the metallic electrode layer 115, and the second barrier layer 126 are successively blanket deposited on the semiconductor layer 110 and then all patterned in a subsequent etching step to form the drain electrode 116 and the source electrode 130 as depicted in FIG. 1A. The first barrier layer 124, the metallic electrode layer 115, and the second barrier layer 126 may form a multi-layer structure that is patterned to remove portions thereof to form separate electrodes of the semiconductor electronic device 100.

As depicted in FIG. 1B, the drain electrode 116 comprises a lower surface 118 disposed proximate to the substrate 102 (e.g., with the first barrier layer 124 being disposed between the lower surface 118 and the semiconductor layer 110), an upper surface 120, and a drain sidewall 122 extending between the lower surface 118 and the upper surface 120. After the multi-layer structure is etched, the drain sidewall 122 may be exposed between first barrier layer 124 and the second barrier layer 126. That is, the drain electrode 116 is exposed to the chemical constituents of the environment of the first patterned electrode structure 112 after the patterning of the multi-layer structure. In embodiments, the second patterned electrode structure 114, including the source electrode 130, is formed in the same manner (e.g., by patterning the multi-layer structure of the first barrier layer 124, the metallic electrode layer, and the second barrier layer 126). As such, the source electrode 130 may comprise a source sidewall 131 that is also exposed to the environment after the patterning of the multi-layer structure.

Such exposure of the drain electrode 116 and the source electrode 130 may lead to degradation of performance of the semiconductor electronic device 100 due to the composition of the source electrode 130 and the drain electrode 116. Copper, for example, is highly susceptible to oxidation, especially at elevated temperatures of 300° C. or more. Such environmental conditions conducive to oxidation may occur during the fabrication process of the semiconductor electronic device 100. For example, as depicted in FIG. 1A, an oxide-containing passivation layer 144 is disposed on the substrate 102 after formation of the first and second patterned electrode structures 112 and 114. The oxide-containing passivation layer 144 may be formed from a variety of different materials (e.g., SiO₂, Al₂O₃) depending on the implementation. In embodiments, the oxide-containing passivation layer 144 is formed via PECVD, where the substrate 102 is placed in a PECVD chamber after the first and second patterned electrode structures 112 and 114 have been formed thereon. The substrate 102 may be heated to a suitable deposition temperature in the chamber (e.g., between 300° C. and 400° C.) and exposed to chemical constituents of the oxide-containing passivation layer 38 at a suitable pressure while a plasma is present in the deposition chamber to facilitate reaction of the constituents on the substrate 102. In such a case, the exposed drain and source sidewalls 122 and 131 may be exposed to oxides at sufficiently elevated temperatures that are conducive to formation of metal oxide layers thereon.

If left exposed after patterning, metal oxide layers may form on the drain and source sidewalls 122 and 131. Such metal oxide layers may not conduct electricity to the same extent as the remainder of the drain and source electrodes 116 and 130, leading to variations in performance of the semiconductor electronic device 100. For example, metal oxide layers formed at the exposed source and drain sidewalls 122 and 131 may change the effective area of the drain and source electrodes 116 and 130. As depicted in FIG. 1C, for example, the semiconductor electronic device 100 comprises first gate overlap region 136 where the source electrode 130 extends over the gate electrode 106 (e.g., overlaps the gate electrode 106 in the Z-direction depicted in FIG. 1C) and a second gate overlap region 140 wherein the drain electrode 116 extends over the gate electrode 106. The first gate overlap region 136 is depicted as having a length 138 in a direction extending parallel to the device surface 103 (e.g., the X-direction depicted in FIG. 1C), while the second gate overlap region 140 is depicted to have a length 142 in the direction parallel to the device surface 103. The metal oxide layers formed at the drain and source sidewalls 122 and 131 may lead to variations in the first and second gate overlap regions 136 and 140 by changing the effective area of the drain and source electrodes 116 and 130. As a result of the exposure of the drain and source sidewalls 122 and 131 to oxides under conditions conducive to oxidation, the lengths 138 and 142 may differ from one another in inconsistent ways. Such variation in the gate overlap regions 136 and 140 may impact performance of the semiconductor electronic device 100 in various ways. For example, variation in the lengths 138 and 142 by as little as 1 μm may impact various operating parameters of the semiconductor electronic device 100, including threshold voltage, scattering parameters, electron mobility, and leakage current. Variation in such operating parameters may adversely affect the operation of the component incorporating the semiconductor electronic device (e.g., a touch panel device, a display, or the like).

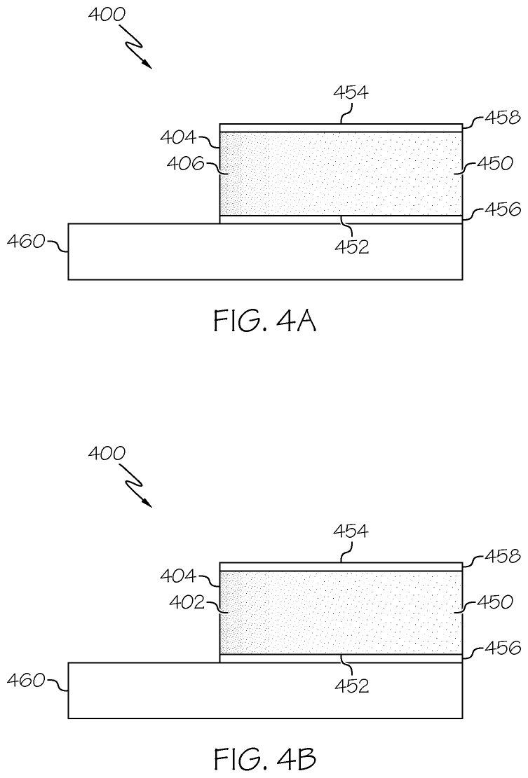

To prevent metal oxide formation at the drain and source sidewalls 122 and 131, the semiconductor electronic device 100 comprises a drain sidewall barrier layer 128 disposed on the drain sidewall 122 and a source sidewall barrier layer 132 disposed on the source sidewall 131. In embodiments, the drain sidewall barrier layer 128 and the source sidewall barrier layer 132 are magnesium oxide barrier layers having a thickness (e.g., in the X-direction depicted in FIGS. 1A-1C, or in a direction extending perpendicular to the upper and lower surfaces 118 and 120 depicted in FIG. 1B) that is greater than or equal to 1 nm and less than or equal 5 nm. In embodiments, the drain and source sidewall barrier layers 128 and 132 are formed via the processes described herein such that they extend locally over the drain and source sidewalls 122 and 131. For example, as described herein with respect to FIGS. 4A and 4B, a manganese precursor may be exposed to the drain and source sidewalls 122 and 131 that diffuses as a metallic phase into the drain and source electrodes 116 and 130 via the drain and source sidewalls 122 and 131. The manganese within the drain and source electrodes 116 and 130 subsequently reacts with oxygen to form a magnesium oxide barrier layer at the drain and source sidewalls 122 and 131. Additional components of the semiconductor device 100 (e.g., the first and second barrier layers 124 and 126, the semiconductor layer 110, etc.) may be resistant to such diffusion of the manganese precursor and not contain any manganese during the subsequent oxygen exposure such that the drain and source sidewall barrier layers 128 and 132 extend locally over the drain and source sidewalls 122 and 131 between the first and second barrier layers 124 and 126.

The manganese oxide sidewall barrier layers described herein (e.g., the drain and source sidewall barrier layers 128 and 132) may comprise a manganese oxide MnOₓ and the metal out of which the drain and source electrodes 116 and 130 are formed (e.g., copper). In embodiments, the MnOₓ concentration within the drain and source sidewall barrier layers 128 decreases with increasing distance from the drain and source sidewalls 122 and 131. The MnOₓ concentration may be at a maximum at surfaces defining the drain and source sidewalls 122 and 131. In embodiments, the Mn concentration within the drain and source sidewall barrier layers 128 and 132 decreases following an error function with increasing distance from the from the drain and source sidewalls 122 and 131. The Mn concentration within the drain and source sidewall barrier layers 128 and 132 may vary depending on the thickness of the drain and source electrodes 116 and 130. In embodiments, the drain and source sidewall barrier layers 128 and 132 are 10 nm thick, and the Mn concentration within the drain and source sidewall barrier layers 128 and 132 varies from greater than or equal to 0.5 wt. % to less than or equal to 20 wt. % (e.g., at the sidewall surface). MnOₓ may serve as a barrier to prevent further oxidation of the drain and source electrodes 130 during the fabrication process of the semiconductor electronic device 100. In embodiments, the drain and source sidewall barrier layers 128 and 132 facilitate maintaining a variation in the lengths 138 and 142 of the first and second gate overlap regions 136 and 140 below a predetermined threshold. For example, in embodiments, a difference between the lengths 138 and 142 is maintained to less than equal to 100 nm (e.g., less than or equal to 50 nm, less than or equal to 10 nm, less than or equal to 5 nm). As a result, performance of the semiconductor electronic device 100 may be consistently maintained with other semiconductor electronic devices fabricated via the same process, thereby improving overall operating performance.

While FIGS. 1A, 1i, and 1C, depict manganese oxide containing sidewall barrier layers being formed only on sidewalls of the drain and source electrodes 116 and 130, it should be appreciated the methods described herein may be used to form manganese oxide barrier layers at various alternative locations of semiconductor electronic devices. To illustrate, in the example depicted in FIGS. 1A, 1B, and 1C, sidewall barrier layers may be formed on the gate electrode 106 (e.g., on both sidewalls thereof). Such sidewall barrier layers on the gate electrode 106 may facilitate more precise patterning of the gate electrode 106 (e.g., by preventing oxidation of the electrode) with tighter tolerances to provide more consistent channel control. The barrier layer formation techniques may be applied to any metallic layer of a semiconductor device. For example, in embodiments, the semiconductor electronic device 100 of FIGS. 1A, 1B, and 1C may include additional metallic layers (e.g., disposed on the oxide-containing passivation layer 144). The manganese oxide barrier layers described herein may be applied to any metallic structure within a semiconductor electronic device where oxidation prevention may be desired.

It should also be appreciated that the manganese oxide barrier layers described herein are also applicable to devices other than the bottom gate TFT device depicted in FIGS. 1A, 1B, and 1C. The sidewall barrier layers described herein may be formed in TFT devices having any configuration (e.g., bottom gate, top gate, bottom contact, top contact, etc.). Moreover, the manganese oxide barrier layers described herein may also be used in non-transistor semiconductor devices (e.g., capacitors, diodes, and the like). In embodiments, the sidewall barrier layers described herein may be used in any semiconductor electronic device containing metallic electrodes rendering the desired oxidation prevention. In embodiments, the sidewall barrier layers described herein may be most useful to semiconductor electronic devices having electrode sizes that are less than or equal to 5 μm. For example, the sidewall barrier layers described herein may be particularly advantageous in semiconductor electronic devices having electrode line widths of less than or equal to 1 μm and/or thicknesses of greater than or equal to 200 nm and less than or equal to 500 nm. Examples of such semiconductor devices may include capacitors, TFT devices, diodes, and the like.

The semiconductor electronic devices described herein may be used in various electronic components. As described herein, the sidewall barrier layers may have relatively low thickness (e.g., less than or equal to 5 nm) and minimal impact on the optical performance of transparent or emissive devices. Given this, the semiconductor electronic devices described herein may be used in various display applications. The sidewall barrier layers described herein may also be employed in touch panel displays utilizing copper (or other metal) metallic electrodes. As such, the semiconductor electronic devices described herein may be used in a wide variety of devices and applications.

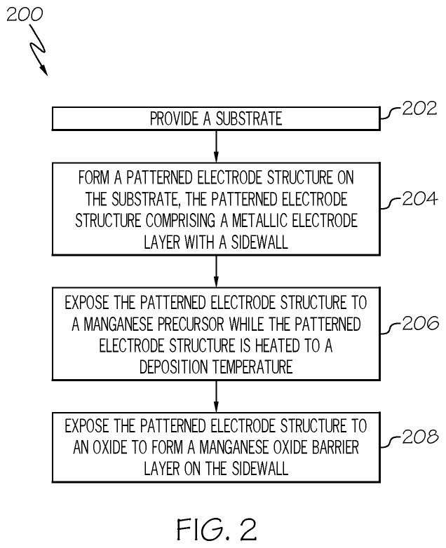

FIG. 2 depicts a flow diagram of a method 200 of forming a manganese oxide barrier layer on a sidewall of a semiconductor electronic device. The method 200 may be used to form various different semiconductor electronic devices where sidewall passivation is needed for a metallic electrode. For example, the method 200 may be used to construct the semiconductor electronic device 100 described herein with respect to FIGS. 1A, 1B, and 1C. A wide variety of semiconductor devise (e.g., TFT devices, capacitors, diodes, and the like) may be formed via the method 200.

In a step 202, a substrate is provided. The substrate may provide a structural base for the formation of additional components of the semiconductor electronic device. The substrate may be constructed of a wide variety of materials. For example, in embodiments, the substrate is similar to the substrate 102 described herein with respect to FIG. 1A, and may be constructed of a glass, glass-ceramic, or ceramic material. In embodiments, the substrate is a plastic-based substrate.

In step 204, a patterned electrode structure is formed on the substrate. The patterned electrode structure may include a metallic electrode layer constructed of a pure metal (e.g., copper, gold, or silver). The form of the patterned electrode structure may vary depending on the nature of the semiconductor electronic device being formed via the performance of the method 200. Moreover, various components of the semiconductor electronic device may be formed on the substrate prior to formation of the patterned metallic structure. In an example where a bottom gate TFT device is formed, such as the semiconductor electronic device 100 described herein, the patterned electrode structure may correspond to the first patterned electrode structure 112 and/or the second patterned electrode structure 114. In such a case, the method 200 may include formation of the gate electrode 106, the dielectric layer 109, and the semiconductor layer 110 prior to performance of the step 204.

Formation of the patterned electrode structure may include blanket deposition of a pure metallic electrode layer on the substrate provided in the step 202 (or any intervening structures disposed thereon) via any suitable technique (e.g., sputtering). In embodiments, the pure metallic electrode layer is constructed of copper, gold, or silver, and comprises a thickness that is greater than or equal to 100 nm and less than or equal to 500 nm. Depending on the type of substrate used or the composition of any intervening structures disposed thereon, the patterned electrode structure may include one or more barrier layers. As such, the one or more barrier layers may be blanket deposited on the substrate in addition to the pure metallic electrode layer. After blanket deposition, the multi-layer structure (e.g., including the pure metallic electrode layer and the one or more barrier layers) may be patterned (e.g., via a suitable etching technique) into the patterned electrode structure. As a result of the patterning, at least one sidewall of the pure metallic electrode layer may be exposed (e.g., uncovered by any other layer of the multi-layer structure), leaving the sidewall susceptible to oxidation and subsequent device performance degradation.

In a step 206, the patterned electrode structure is exposed to a manganese precursor while the patterned electrode structure is heated to a deposition temperature. In embodiments, manganese may have a temperature-dependent diffusion constant in the pure metal (e.g., copper) out of which the pure metallic electrode layer of the patterned electrode structure is constructed. For example, manganese may possess a relatively high diffusion constant in polycrystalline copper at temperatures that are greater than or equal to 300° C. and less than or equal to 400° C. (e.g., greater than or equal to 350° C. and less than or equal to 400° C.). As such, in embodiments, the substrate and patterned electrode structure are heated to a suitable deposition temperature and exposed to the manganese precursor in a deposition chamber, such that the manganese of the manganese precursor may diffuse into the pure metallic electrode layer at the exposed sidewall such that manganese is present as a metallic phase within the pure metallic electrode layer. In embodiments, other components of the semiconductor electronic device that are exposed to the manganese precursor within the deposition chamber (e.g., dielectric layers, semiconductor layers, barrier layers disposed on the electrode layer) do not comprise as high of a diffusion constant with manganese as the metallic electrode layer. Given this, manganese may be purged from the deposition chamber after an exposure period and remain in the patterned electrode structure only at or near the exposed sidewall, resulting in barrier layers only being subsequently formed at the sidewall, preventing adverse effects (e.g., increased line resistance in electrodes) of the manganese in such other components.

Various manganese precursors may be used consistent with the present disclosure. In embodiments, for example, (MeCp)Mn(CO)3, (EtCp)2Mn, or Cp2Mn may be used as the manganese precursor. In embodiments, the manganese precursor is a manganese amidinate having the structure:

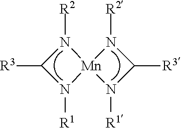

where R¹, R², R³, R^{1′}, R^{2′}, and R^{3′} are groups made from one or more non-metal atoms. In embodiments, R1, R2, R1′ and R2′ are isopropyl groups and R3 and R3′ are n-butyl groups. In embodiments, the manganese aminidate may comprise manganese(II)(R1-R2-amidinate)R3 or manganese(II) (R1′-R2′-amidinate)R3′, where R1, R2, R1′ and R2′ are isopropyl groups, and R3 and R3′ are n-butyl groups. In embodiments, the manganese amidinate comprises Bis (N,N diisopropylpentanamidinato) manganese (II) having the structure

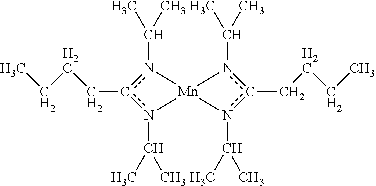

and is supplied to the deposition chamber via a bubbler in fluid communication with the deposition chamber.

In embodiments, the manganese precursor may be heated to a temperature within the bubbler of at least 75° C. (e.g., greater than or equal to 75° C. and less than or equal to 100° C.), converted to a gas, and delivered to the deposition chamber while the substrate and patterned electrode are heated to the deposition temperature. The patterned electrode structure may be exposed to the manganese precursor while the pressure in the deposition chamber is greater than or equal to 0.1 Torr and less than or equal to 100 Torr (e.g., greater than or equal to 1 Torr and less than or equal to 10 Torr) to promote diffusion of the manganese while limiting processing time. The exposure to the manganese precursor may occur for a predetermined period such that a sufficient amount of manganese diffuses into the metallic electrode layer. In embodiments, the predetermined period is greater than or equal to 1 second to provide manganese to the sidewall and less than or equal to 20 minutes. In embodiments, the deposition period is greater than or equal to 3 minutes and less than or equal to 6 minutes. Such a period creates a sufficiently thick sidewall barrier layer while limiting processing times. Moreover, exposure to the manganese precursor for greater than 20 minutes may lead to increased line resistance within the metallic electrode layer, and reduced device performance. It should be appreciated that the period of exposure to the manganese precursor may depend on the deposition temperature to which the patterned electrode structure is heated. For example, if the deposition temperature is greater than or equal to 350° C., the deposition temperature may be less than or equal to 1 minute (e.g., greater than or equal to 1 second and less than or equal to 1 minute).

After being exposed to the manganese precursor, the patterned electrode structure is exposed to an oxide in a step 208. In embodiments, prior to being exposed to the oxide, the deposition chamber is purged of the manganese precursor such that the remaining manganese largely is contained within the metallic electrode layer at the sidewall to avoid formation of manganese oxide layers at unwanted locations of the semiconductor electronic device. The oxide may react with the manganese remaining in the metallic electrode layer at the sidewall to form a magnesium oxide barrier layer having an MnOx concentration that decreases as a function of distance from the sidewall. The MnOx may prevent oxidation of the metallic electrode layer and maintain conductivity thereon to a greater extent than if the magnesium oxide barrier layer was not formed and therefore help to maintain electrical performance of the semiconductor electronic device. In embodiments, a native metal oxide layer at the sidewall may have formed prior to exposure to the manganese precursor. In such embodiments, the native oxide may be reduced prior to performance of the steps 206 and 208 to facilitate diffusion of the manganese into the metallic electrode layer. In embodiments, H₂ may be introduced into the deposition chamber at a temperature of greater than or equal to 300° C. for native oxide reduction to prepare for formation of the magnesium oxide sidewall barrier layer.

In embodiments, the steps 206 and 208 of the method 200 are performed during the process of fabricating various other portions of the semiconductor electronic device. For example, in embodiments, the semiconductor electronic device may comprise an oxide-containing passivation (or other) layer that contacts the sidewall exposed by the patterning of the patterned electrode structure. Such oxide-containing passivation layers may involve exposure of the patterned electrode structure to conditions that are conducive to oxidation of the metallic electrode layer. For example, in embodiments, an oxide-containing passivation layer may be formed via a PECVD process.

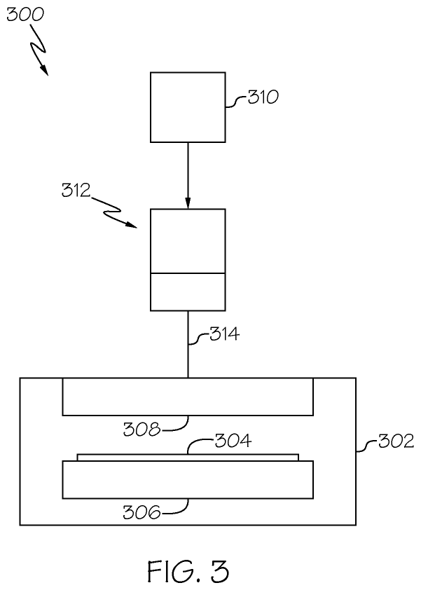

FIG. 3 depicts an example PECVD reactor 300 that may be used to deposit components (e.g., the oxide-containing passivation layer 144 of the semiconductor electronic device 100 described with respect to FIG. 1) of a semiconductor electronic device and form a sidewall barrier layer. The PECVD reactor 300 comprises a PECVD chamber 302 in which constituent gases of the components being generated are introduced and reacted via a plasma enhanced process. The PECVD chamber 302 includes an opening (not depicted) to facilitate introducing a substrate 304 (e.g., the substrate 102 described with respect to FIG. 1) upon which the semiconductor device component is to be formed. The substrate 304 is shown to be disposed on a substrate holder (e.g., anode) 306. In embodiments, the PECVD reactor 300 comprises a showerhead (e.g., cathode) 308 through which constituent gases enter the PECVD chamber 302. In embodiments, the PECVD reactor 300 further comprises an RF source (not depicted) and associated circuitry that are electrically coupled to the showerhead 308. An RF signal may be supplied to the showerhead 308 and lead to an electrical discharge extending between the showerhead 308 and the substrate holder 306. The electric discharge may ionize atoms in the constituent gases such that the ionized atoms are electrically attracted to the substrate 304 and undergo chemical reactions thereon.

It should be appreciated that the diagram of the PECVD reactor 300 of FIG. 3 is simplified herein for purposes of discussion. For example, in embodiments, the substrate holder 306 comprises one or more heating elements for heating the substrate 304 to suitable reaction temperatures for component formation. A pump (not depicted) may also be in fluid communication with the interior of the PECVD chamber 302 in order to regulate the pressure within the PECVD chamber 302 and remove chemical constituents therefrom once a component deposition process is complete. Gas injectors (not depicted) regulating the flow of various chemical constituents of the components being formed may also be in fluid communication with the interior of the PECVD chamber 302. For example, to deposit an oxide-containing passivation layer such as SiO₂, a silicon gas source (e.g., a silane) and an oxygen gas source (e.g., oxygen or nitrous oxide) may be in fluid communication with the interior of the PECVD chamber 302. Flow of the constituent gases may be regulated by valves.

Referring still to FIG. 3, the PECVD reactor 300 further comprises a carrier gas source 310 in fluid communication with the PECVD chamber 302. The carrier gas source 310 may provide a carrier gas for circulating constituents into the PECVD chamber 302. In embodiments, the carrier gas is an inert gas (e.g., Argon) that may serve as a dilutant to prevent undesired gas-phase reactions. It should be appreciated that any number of gas injectors and carrier gas sources may be used consistent with the present disclosure, as the number of such components may vary depending on the semiconductor electronic device being formed and the chemical constituents being reacted.

The PECVD reactor 300 further comprises a bubbler 312 dedicated to introducing the manganese precursor for forming the sidewall barrier layers described herein. The bubbler 312 contains the manganese precursor (e.g., described with the step 206 of the method 200 described herein with respect to FIG. 2). In embodiments, the manganese precursor may be solid at room temperature, but have a melting point of approximately 60° C. The bubbler 312 may heat the manganese precursor to above the melting point to form a manganese precursor gas that is delivered to the PECVD chamber 302 via a carrier gas from the carrier gas source 310. As depicted, the bubbler 312 is in fluid communication with the showerhead 308 via a delivery line 314. In embodiments, to facilitate delivery of the manganese precursor to the substrate 304, the delivery temperature thereof at the showerhead 308 may be greater than or equal to 70° C. and less than or equal to 100° C. As such, the showerhead 308 and delivery line 314 may be heated to the delivery temperature to facilitate formation of the sidewall barrier layers described herein.

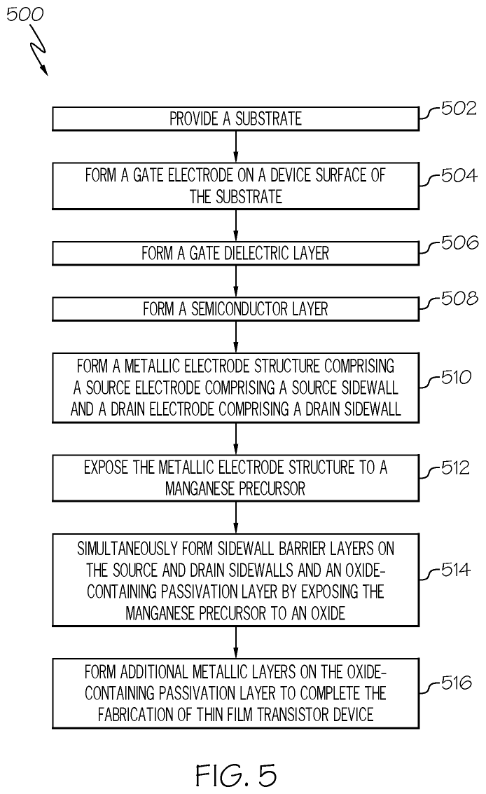

By incorporating the bubbler 312, the PECVD reactor 300 facilitates formation of the sidewall barrier layers described herein during the formation of other components of semiconductor electronic devices. For example, as described herein with respect to FIG. 5, the PECVD reactor 300 may facilitate formation of sidewall barrier layers on source and gate sidewalls of a TFT device during the formation of an oxide-containing passivation layer thereon. For example, after an exposed sidewall of a metallic electrode layer of a semiconductor electronic device disposed in the PECVD chamber 302 is exposed to a manganese precursor via the bubbler 312, an oxide introduced into the PECVD chamber 302 during deposition of a subsequent layer may react with manganese at the sidewall to form a sidewall barrier layer as the subsequent layer is being formed. Such a process allows for the generation of the sidewall barrier layers described herein with minimal interruption of existing fabrication processes.

FIGS. 4A and 4B depict stages of forming a manganese oxide barrier layer 402 at a sidewall 404 of a patterned electrode structure 400 of a semiconductor electronic device. In embodiments, the patterned electrode structure 400 is a source or drain electrode of a TFT device. For example, as depicted, the patterned electrode structure 400 is similar in structure to the first patterned electrode structure 112 described herein with respect to FIG. 1, comprising an electrode 450 with a first surface 452, a second surface 454, and the sidewall 404 extending between the first surface 452 and the second surface 454. The electrode 450 is disposed on a semiconductor layer 460. A first barrier layer 456 contacts the first surface 452 and is disposed between the electrode 450 and the semiconductor layer 460, while a second barrier layer 458 contacts the second surface 454. In embodiments, the electrode 450 is a pure metallic electrode constructed of copper, gold, or silver. In embodiments, the patterned electrode structure 400 is formed on the semiconductor layer 460 via blanket deposition of the first barrier layer 456, a metallic electrode layer, and the second barrier layer 458 and subsequent patterning of the multi-layer structure.

FIG. 4A depicts the patterned electrode structure 400 just after exposure to a manganese precursor 406. The manganese precursor 406 may be any of the manganese precursors described herein (e.g., a manganese amidinate). For example, the patterned electrode structure 400 may be disposed on the substrate holder 306 of the PECVD reactor 300 described herein with respect to FIG. 3, and subsequently heated to a temperature of approximately 350° C. At such a temperature, the diffusion constant of manganese within the electrode 450 (e.g., constructed of copper) may be relatively high. The bubbler 312 may then be heated to generate the gaseous manganese precursor 406, which may be directed into the PECVD chamber 302 via the heated delivery line 314 and the showerhead 308. Plasma in the PECVD chamber may facilitate collection of the manganese precursor 406 on the electrode 450. The sidewall 404 may be the only exposed portion of the electrode 450, such that manganese from the manganese precursor 406 may diffuse into and be disposed within the electrode 450 at the sidewall 404 as a metallic phase. As depicted, the manganese may be present at a concentration that decreases with increasing distance from the sidewall 404.

After the manganese is deposited on the electrode 450, the manganese precursor 406 may be evacuated form the PECVD chamber 302, such that the remaining manganese is largely within the electrode 450 at the sidewall 404. After the evacuation, an oxide may be introduced into the PECVD chamber 302. The oxide may be from an oxide precursor gas directed into the PECVD chamber 302 during deposition of an additional component of the semiconductor electronic device of the patterned electrode structure 400. In embodiments, the oxide in the PECVD chamber 302 may react with the manganese disposed at the sidewall 404 to form a manganese oxide barrier layer 402 that comprises a manganese oxide and the metal out of which the electrode 450 is constructed. The manganese oxide barrier layer 402 may have a thickness of greater than or equal to 1 nm and less than or equal to 5 nm. In embodiments, the manganese oxide concentration within the manganese oxide barrier layer 402 decreases with increasing distance from the sidewall 404 in accordance with the manganese present in the electrode 450 prior to introduction of the oxide. As exemplified by the process depicted in FIGS. 4A and 4B, the sidewall barrier layers described herein may be formed in a PECVD chamber currently used in existing fabrication processes with minimum disruption and build time increases.

Referring now to FIG. 5, a flow diagram of a method 500 of fabricating a TFT device including source and gate sidewall barrier layers is depicted. In embodiments, the method 500 may be performed using the PECVD reactor 300 described herein with respect to FIG. 3. In embodiments, the method 500 may be used to form the semiconductor electronic device 100 described herein with respect to FIG. 1, though it should be appreciated that the method 500 may be used to form TFT devices having alternative structures and configurations. In a step 502, a substrate is provided. The substrate may comprise a glass, a glass-ceramic, a ceramic, a plastic-based substrate, or any other suitable material depending on the implementation. In embodiments, the substrate may have dimensions (e.g., a length and/or a width) of 5 μm or less (e.g., less than or equal to 5 μm, less than or equal to 1 μm). In step 504, a gate electrode is formed on a device surface of the substrate. For example, referring to the semiconductor electronic device 100 described herein with respect to FIGS. 1A, 1, and 1C, a metallic electrode layer constructed of copper may be blanket deposited on the device surface 103 via any suitable technique, and subsequently patterned to form the gate electrode 106. In embodiments, sidewall barrier layers may be formed on sidewalls of the gate electrode by, for example, performance of the method 200 described herein with respect to FIG. 2 after the gate electrode is formed. Such sidewall barrier layers on the gate electrode may allow for more precise patterning of the gate electrode (e.g., by preventing oxide formation) and therefore better control of the operation of the semiconductor electronic device.

In steps 506 and 508, a gate dielectric layer and semiconductor layer are formed on the gate electrode. Layers of the constituent materials of the gate dielectric layer and the semiconductor layer may be blanket deposited onto the substrate via any suitable technique and patterned based on the configuration of the semiconductor electronic device. In a step 510, a metallic electrode structure comprising a source electrode with a source sidewall and a drain electrode with a drain electrode sidewall are formed on the substrate. In embodiments, the source and drain electrodes are formed via deposition and patterning of the same multi-layer structure. For example, as described herein with respect to the semiconductor electronic device 100 of FIGS. 1A, 1B, and 1C, the drain electrode 116 and the source electrode 130 are simultaneously formed via blanket deposition of the multi-layer structure comprising the first barrier layer 124, a metallic electrode layer, and the second barrier layer 126; and then patterning the multi-layer structure via an etching step. In that example, the etching may remove a portion of the multilayer structure to simultaneously expose the drain sidewall 122 and the source sidewall 131 between the first and second barrier layers 124 and 126. In embodiments, the source and drain electrode may be formed in separate deposition steps.

In a step 512 the metallic electrode structure is exposed to a manganese precursor. For example, in embodiments, the substrate having the metallic electrode structure disposed thereon may be placed in a deposition chamber. For example, the PECVD chamber 302 described herein with respect to FIG. 3 may serve as the deposition chamber. After the substrate is placed into the PECVD chamber 302, the PECVD chamber 302 may be purged of any gasses present therein, and pumped to a baseline pressure (e.g., less than or equal to 10 mTorr). In embodiments, as or after the PECVD chamber 302 is pumped to the baseline pressure, heating elements in the substrate holder 306 may heat the substrate to a predetermined deposition temperature. In embodiments, the deposition temperature is based on a diffusion constant of manganese in the metal out of which the metallic electrode layer is constructed. For example, in embodiments, the metallic electrode layer is copper and the substrate is heated to a temperature that is greater than or equal to 300° C. and less than or equal to 400° C. (e.g., greater than or equal to 340° C. and less than or equal to 360° C., or greater than or equal to 345° C. and less than or equal to 355° C.). At the deposition temperature, the diffusion constant of manganese within copper may be relatively high to facilitate manganese entering the metallic electrode layer at the exposed sidewall.

In embodiments, after the substrate is heated to the deposition temperature, the bubbler 312 is heated to a temperature above the melting point of the manganese precursor (e.g., greater than or equal to 60° C.) and directed into the PECVD chamber 302 via a heated delivery line 314 (e.g., heated to greater than or equal to 75° C. and less than or equal to 100° C.). The manganese precursor may be carried by a carrier gas from the carrier gas source 310 such that the PECVD chamber is maintained at a predetermined deposition pressure for an exposure period. In embodiments, the exposure period is greater than or equal to 1 minute and less than or equal to 20 minutes (e.g., greater than or equal to 3 minutes and less than or equal to 6 minutes) and the deposition pressure is greater than or equal to 0.1 Torr and less than or equal to 100 Torr (e.g., greater than or equal to 1 Torr and less than or equal to 10 Torr). The manganese precursor may diffuse into the metallic electrode via the exposed sidewalls. For example, while fabricating the semiconductor electronic device 100 described herein with respect to FIG. 1, the manganese precursor may diffuse into the drain electrode 116 and the source electrode 130 at the drain and source sidewalls 122 and 131, respectively. As depicted in FIG. 4A, the manganese precursor may be present at the exposed sidewalls in a concentration gradient that decreases with increasing distance from each of the sidewalls. In embodiments, after exposure to the manganese precursor, the PECVD chamber 302 is purged and again pumped to a baseline pressure. Such a step may beneficially remove manganese from portions of the semiconductor electronic device where barrier layer formation is not desired.

In a step 514, sidewall barrier layers are simultaneously formed on the source and drain sidewalls during the deposition of an oxide-containing passivation layer on the patterned electrode structure. For example, after the PECVD chamber 302 is purged, chemical constituents of an oxide-containing passivation layer may be flowed into the PECVD chamber 302. The composition of the constituents may vary depending on the oxide-containing passivation layer being formed. For example, in embodiments, the oxide-containing passivation layer 144 of the semiconductor electronic device 100 described herein with respect to FIG. 1 may be an SiOₓ passivation layer. In such embodiments, the chemical constituents may comprise a silicon precursor (e.g., a silane) and the oxygen precursor may comprise N₂O. After the pressure within the PECVD chamber 302 is increased to a desired deposition temperature, an RF signal may be supplied to the showerhead 308 to cause electric discharge between the showerhead 308 and the substrate holder 306. The constituent gases may be ionized to facilitate migration thereof to the surface of the semiconductor electronic device and the exposed source and drain sidewalls. The oxide may react with the manganese that previously diffused into the source and drain electrodes to form manganese oxide source and drain sidewall barrier layers (e.g., the drain and source sidewall barrier layers 128 and 132 described herein with respect to FIG. 1A). Additionally, the oxide may react with the other constituents of the oxide-containing passivation layer to form the passivation layer over the patterned electrode structure. After a deposition period to form a passivation layer having a desired thickness, the PECVD chamber may again be purged and pumped to a baseline pressure, and the substrate may be removed from the PECVD chamber 302.

In a step 512, additional metallic layers may be formed on the oxide-containing passivation layer to complete fabrication of the TFT device. For example, in embodiments, the TFT device may include an additional gate disposed on the oxide-containing passivation layer. Metallic contacts may also be deposited on the oxide-containing passivation layer that overlay the source and drain electrodes. Any number of additional metallic layers may be included on the TFT device consistent with the present disclosure.

It should be appreciated that the steps of the method 500 may occur in various different orders defending on the configuration of the TFT device being fabricated. For example, in the fabrication of a top-gate TFT device, the patterned electrode structure may be deposited on the substrate prior to formation of the semiconductor layer or the gate electrode. Moreover, depending the implementation, the semiconductor layer may be formed on the source and drain electrodes. The sidewall barrier layers described herein also do not need to be formed within a PECVD chamber, but may be formed in a separate deposition step. Generally, the sidewall barrier layers described herein are useful in any application where a metallic electrode layer constructed of gold, copper, or silver may be exposed to an oxide at an elevated temperature.

In view of the foregoing, it should be understood that utilizing a manganese precursor and subsequent oxide exposure may be used to form manganese oxide barrier layers extending locally over exposed sidewalls of a patterned electrode structure of a semiconductor electronic device. Such sidewall barriers may prevent oxidation of electrodes at the exposed sidewalls, thereby facilitating the geometry of the electrodes being more precisely defined than in fabrication methods not including such sidewall barrier layers. The sidewall barrier layers described herein are especially beneficial in fabrication methods where pure metallic electrodes are exposed to oxides in an environment conducive to oxidation of the electrodes. Moreover, the sidewall barrier layers described herein may be formed with minimal disruption to existing fabrication process. Manganese precursors may be added to existing PECVD reactors used to form passivation layers with minimal reconfiguration of the build process being needed. As such, the methods described herein improve device performance without hindering production efficiency.

While exemplary embodiments have been described herein, it will be understood by those skilled in the art that various changes in form and details may be made therein without departing from the scope encompassed by the appended claims.

1. A semiconductor device comprising:
a substrate including a device surface;
a patterned metallic electrode disposed on the substrate, the patterned metallic electrode being formed of one or more of copper, gold, and silver, the patterned metallic electrode comprising a lower surface proximate to the substrate, an upper surface, and a sidewall extending between the lower surface and the upper surface; and
a sidewall barrier layer extending over the sidewall.

2. The semiconductor device of claim 1, wherein the sidewall barrier layer comprises a magnesium oxide barrier layer.

3. The semiconductor device of claim 2, wherein the sidewall barrier layer comprises a thickness of greater than or equal to 1 nm and less than or equal to 5 nm.

4. The semiconductor device of claim 2, further comprising:
a first barrier layer contacting the lower surface and disposed between the patterned metallic electrode and the substrate; and
a second barrier layer contacting the upper surface, wherein neither the first barrier layer nor the second barrier layer directly contacts the sidewall.

5. The semiconductor device of claim 4, wherein the sidewall barrier layer is disposed between the first barrier layer and the second barrier layer directly on the sidewall.

6. The semiconductor device of claim 1, further comprising an oxide-containing passivation layer disposed on the patterned metallic electrode, the oxide-containing passivation layer directly contacting at least a portion of the sidewall barrier layer.

7. The semiconductor device of claim 1, further comprising:
a gate electrode disposed on the substrate;
a dielectric layer disposed on the gate electrode;
a semiconductor layer disposed on the dielectric layer;
a source electrode disposed on a first portion of the semiconductor layer; and
a drain electrode disposed on a second portion of the semiconductor layer, wherein:
the source electrode and the drain electrode overlap the gate electrode in a direction extending perpendicular to the device surface at first and second gate overlap regions; and
the patterned metallic electrode is one of the source electrode and the drain electrode such that the sidewall barrier layer directly contacts the source electrode or the drain electrode.

8. The semiconductor device of claim 7, wherein the other of the source electrode and the drain electrode that is not the patterned metallic electrode comprises a lower surface proximate to the substrate, an upper surface, and an additional sidewall extending between the lower surface and the upper surface, the semiconductor device further comprising an additional sidewall barrier layer disposed locally over the additional sidewall.

9. The semiconductor device of claim 8, wherein lengths of the first and second gate overlap regions differ from one another by less than or equal to 10 nm.

10. The semiconductor device of claim 8, further comprising a passivation layer disposed on the source electrode and the drain electrode, the passivation layer containing an oxide, wherein the passivation layer directly contacts at least a portion of the sidewall and the additional sidewall.

11. The semiconductor device of claim 10, further comprising an additional metallic layer disposed on the source electrode and the drain electrode.

12. The semiconductor device of claim 8, further comprising a copper barrier layer disposed locally over the gate electrode, the copper barrier layer directly contacting the gate electrode.

13. The semiconductor device of claim 1, wherein the patterned metallic electrode is a component of a thin film transistor.

14. The semiconductor device of claim 11, wherein the thin film transistor is a component of a touch panel display.

15. A method of fabricating a semiconductor electronic device, the method comprising:
providing a substrate;
forming a patterned electrode structure on the substrate, the patterned electrode structure comprising:
a first barrier layer disposed on the substrate;
a metallic electrode layer disposed on the first barrier layer, the metallic electrode layer being formed of one or more of copper, gold, and silver; and
a second barrier layer disposed on the upper surface of the metallic electrode layer, wherein the first barrier layer, the metallic electrode layer, and the second barrier layer are patterned such that a sidewall of the metallic electrode layer is exposed between the first barrier layer and the second barrier layer;
heating the substrate to a deposition temperature of at least 300° C.;
exposing the patterned electrode structure to a manganese precursor at the deposition temperature within a deposition chamber for a deposition period, wherein a pressure in the deposition temperature is at least 0.1 Torr during the deposition period, wherein the deposition period is at least 1 second and the manganese precursor selectively migrates the sidewall; and
after exposing the substrate to the manganese precursor, exposing the patterned electrode structure to an oxide that reacts with the manganese precursor to form an MnOₓ barrier layer disposed locally on the sidewall.

16. The method of claim 15, wherein the manganese precursor is a manganese amidinate having the structure 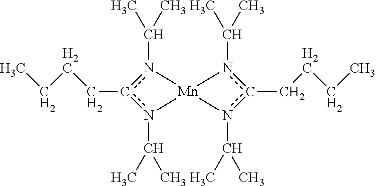
and is supplied to the deposition chamber via a bubbler in fluid communication with the deposition chamber.

17. The method of claim 15, wherein the manganese precursor is a manganese amidinate having the structure 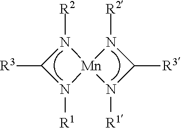
where R¹, R², R³, R^{1′}, R^{2′}, and R^{3′} are groups made from one or more non-metal atoms.

18. The method of claim 17, wherein R1, R2, R1′ and R2′ are isopropyl groups and R3 and R3′ are n-butyl groups.

19. The method of claim 15, further comprising depositing an oxide-containing passivation layer on the patterned electrode structure, the oxide-containing passivation layer at least partially contacting the MnOₓ barrier layer.

20. The method of claim 19, wherein the oxide that reacts with the manganese precursor to form an MnOₓ barrier layer is a component of the oxide-containing passivation layer such that the MnOₓ barrier layer is formed during deposition of the oxide-containing passivation layer.

21. The method of claim 20, wherein the oxide-containing passivation layer is deposited in a plasma enhanced chemical vapor deposition chamber.

22. The method of claim 21, wherein the deposition chamber in which the patterned electrode structure is exposed to the manganese precursor corresponds to the plasma enhanced chemical vapor deposition chamber such that the patterned electrode structure remains in the plasma enhanced chemical vapor deposition chamber both for exposure to the manganese precursor and the deposition of the oxide-containing passivation layer.

23. The method of claim 22, wherein the manganese precursor is introduced into the plasma enhanced chemical vapor deposition chamber via a bubbler in fluid communication with the plasma enhanced chemical vapor deposition chamber, wherein the bubbler is heated to a temperature that is greater than or equal to 75° C. and less than or equal to 100° C. prior to introducing the manganese precursor into the plasma enhanced chemical vapor deposition chamber.

24. The method of claim 15, wherein the semiconductor electronic device is a thin film transistor device.

25. A method of fabricating a thin film transistor, the method comprising:
providing a substrate;
depositing a gate electrode layer on a device surface of the substrate and patterning the gate electrode layer into a gate electrode;
depositing a dielectric layer on the gate electrode layer;
depositing a semiconductor on the dielectric layer;
forming a patterned electrode structure on the channel, the patterned electrode structure comprising a first barrier layer disposed on the semiconductor layer, an electrode layer disposed on the first barrier layer, and a second barrier layer disposed on the electrode layer, wherein the electrode layer comprises a drain portion comprising a drain sidewall and a source portion comprising a source sidewall, the drain sidewall and the source sidewall being disposed over the gate electrode;
simultaneously forming sidewall barrier layers extending over the source and gate sidewalls and an oxide-containing passivation layer on the patterned electrode structure, wherein simultaneously forming the sidewall barrier layers and the oxide-containing passivation layer comprising:
placing the substrate and patterned electrode structure into a plasma enhanced chemical vapor deposition chamber in fluid communication with a bubbler containing a manganese precursor;
flowing the manganese precursor into the deposition chamber for a predetermined period while the substrate and patterned electrode are heated to a deposition temperature; and
flowing chemical components of the oxide-containing passivation layer into the deposition chamber such that an oxide reacts with the manganese precursor to form magnesium oxide sidewalls barrier layers on the source and gate sidewalls.

26. The method of claim 25, wherein the manganese precursor is a manganese amidinate having the structure 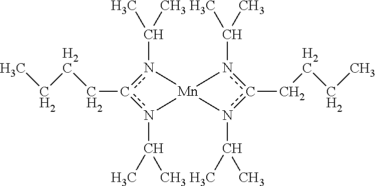
and is supplied to the deposition chamber via a bubbler in fluid communication with the deposition chamber.

27. The method of claim 25, wherein the manganese precursor is a manganese amidinate having the structure 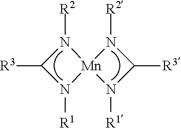
where R¹, R², R³, R^{1′}, R^{2′}, and R^{3′} are groups made from one or more non-metal atoms.

28. The method of claim 27, wherein R1, R2, R1′ and R2′ are isopropyl groups and R3 and R3′ are n-butyl groups.

29. The method of claim 25, wherein the electrode layer is formed of one or more of copper, gold, and silver.

30. The method of claim 25, wherein the electrode layer is formed of pure copper.

31. The method of claim 25, wherein the deposition temperature is greater than or equal to 300° C.

32. The method of claim 25, wherein the deposition temperature is greater than or equal to 350° C.

33. The method of claim 25, wherein the predetermined period is greater than or equal 15 minutes.

34. The method of claim 25, wherein the oxide-containing passivation layer comprises silica.

35. The method of claim 25, further comprising exposing the gate electrode to a manganese precursor at an elevated temperature prior to depositing the dielectric layer thereon.
